(19) United States
(12) Patent Application Publication
(10) Pub. No.: US 2014/0333283 A1
(43) Pub. Date: Nov. 13, 2014

(54) Electrical Energy Measuring System For A Mobile Electrical Power System

(71) Applicant: Marek Miskiewicz, Jawor (PL)

(72) Inventor: Marek Miskiewicz, Jawor (PL)

(21) Appl. No.: 14/358,862

(22) PCT Filed: Nov. 15, 2012
(86) PCT No.: PCT/PL2012/000124

§ 371 Date: May 16, 2014

(30) Foreign Application Priority Data
Nov. 16, 2011 (PL) P.396995

(51) Int. Cl. G01R 21/133

(52) U.S. Cl. CPC G01R 21/133
USPC 324/76.11

(57) ABSTRACT

An energy measuring system for a mobile electrical power system has an electrical energy storage connected to at least one to an electrical energy receiver and/or an electrical energy source, and to an output connectable to a stationary electrical power system. A measuring system includes a first register for measured signals of electrical energy flowing between the mobile storage and the stationary system and a second register for measured signals of electrical energy flowing within the mobile system between the storage and the receiver and/or the source. A switch system transfers a signal from one of its inputs, which is connected to the output of a signal processor,

to a selected one of two outputs, each output connected to a different register depending on a first control input signal. The first control input is connectable to a source based on a status of the connection between the mobile system and the stationary system.

### CROSS REFERENCE TO RELATED APPLICATIONS

This application is a National Stage of PCT Patent Application no. PCT/PL2012/000124, filed 15 Nov. 2012, which claimed priority from Polish patent application no. P.396995, filed 16 Nov. 2011, the contents of which are hereby incorporated by reference.

### TECHNICAL FIELD

The present invention relates to an electrical energy measuring systems adapted to mobile electrical power systems isolated in vehicles, such as electrical and hybrid cars, and to a stationary electrical power system adapted to be connected with such an electrical energy measuring system. In particular, the present invention relates to an electrical energy measuring system for a mobile electrical power system, and in particular for a mobile electrical power system of a vehicle having electrical or hybrid drive. Such a system may also be employed for measuring electrical energy for performing settlements of electrical energy received and supplied by a mobile electrical power system while the mobile system of a vehicle is connected to a stationary electrical power system.

### BACKGROUND

An electrical drive of mechanical vehicles becomes more and more common in consideration of many advantages thereof such as among others a facility of controlling, a simplicity of a driving system construction, smooth regulation of a rotational speed without necessity of using traditional gearboxes, low level of noise, smaller environmental burden, facility of recovering of braking energy or daily equalization of a course of a load of a stationary electrical power system. The above factors should lead to an Increase in popularity of electrical and hybrid vehicles in the future due to ecological and economic considerations.

Technology of electrical vehicles, mainly on account of a high cost of storages (accumulators) of electrical energy, is at present relatively expensive. However taking into account the above described advantages, in many states it has been decided to implement various systems of subsidizations for purchasing such electrical vehicles (in particular cars having hybrid or electrical drives). In consideration of a certain artificiality of such support systems and a lack of a full social acceptance for such a kind of privilege for those purchasing electrical vehicles, these subsidization systems does not satisfy inspired hopes. Therefore it is expected to provide another type of support means for those intending in purchasing electrical vehicles.

One proposition is treating an electrical vehicle having a mobile electrical power system as a mobile, fully authorized participant or entity of an electrical energy market, to whom a preferential trading of electrical energy stored and/or generated therein in a stationary electrical power system, including for example performing important functions improving a stability of a stationary electrical power system such as creation of a source of a reserve electrical power or constituting a reactive power compensator, has been made available.

Figure Pos. I schematically presents an example of a connection of exemplary mobile electrical power systems (MEPS) 11, 21 of vehicles 1, 2 to a stationary electrical power system (SEPS) 3 by means of terminals 351 of charging stations 35. The system MEPS of each of the vehicles 1, 2 comprises—connected to each other by means of the internal electrical energy (EE) transmission system 13, 23—an electrical energy (EE) storage 12, 22, a group of electrical energy sources/receivers and an output 14, 24 connectable to the system SEPS 3 for receiving/supplying an electrical energy respectively from and to the system SEPS 3.

The internal electrical energy transmission systems 13, 23 comprise—connected to each other in the points 131, 231—an electrical energy transmission line 132. 232 of the EE storage connected directly with the EE storage 12, 22, an Input EE transmission line 133, 233 connected directly with the output 14, 24, and a receiver/source EE transmission line 134, 234 connected to the EE sources/receivers of the system MEPS 11, 21. In the vehicle 2, the line 234 bifurcates into two sublines 2341, 2342 connected to different types of EE sources/receivers, such as for example devices operating on renewable energy and non-renewable energy.

In case of the first vehicle 1 which is an electrical vehicle, the EE receiver receiving an electrical energy from the EE storage 12 is an electric motor 15 driving the wheels of the vehicle by means of the mechanical energy redirection system 16.

However the primary EE source in the vehicle 1 is an kinetic energy recovery system 17 recovering energy during vehicle braking, which through the redirection system 16 drives the electrical machine 15, which in turn operating as a generator delivers an electrical energy to the EE storage 12 by the lines 134 and 132. The second vehicle 2 having a hybrid drive, except for the elements 25, 26, 27 analogical to the elements 15, 16, 17 of the first vehicle 1, comprises an additional EE source in a form or a combustion engine 28 driving a generator 29. Optionally, the system 21 may—instead of the engine 28—by provided with an engine 28a driving the wheels of the vehicle or an electrical engine 25 working in generation operation mode through the mechanical energy redirection system 26.

In the system SEPS 3 operate the EE sources 31, 32 converting respectively the first and the second type of a primary energy (the first type is for example a non-renewable primary energy while the second type is for example a renewable primary energy) into electrical energy which is delivered to a transmission-distribution network 33, from which electrical energy is drawn by the stationary receivers 34 and the charging stations 35 fixedly connected to the network. Each of the charging stations 35 is provided with a number of terminals 351 to which the outputs 14, 24 of the systems MEPS 11, 21 of the vehicles 1, 2 may be connected.

In the state of such a presented connection, the EE storages 12, 22 of the systems MEPS may, through the terminals 351 of the charging stations 35, draw an electrical energy from the sources 31, 32 of the system SEPS, or may supply the electrical energy accumulated therein to the system SEPS, for example to the stationary receivers 34 of the system SEPS or to the other systems MEPS connected concurrently to the system SEPS.

In case where the systems SEPS and MEPS are not compatible with each other in consideration of different types of currents, then an EE transmission between these elements is realized by means of appropriate bidirectional current convertors. Such a situation occurs in particular in case when a system SEPS is an alternating current system while a system MEPS is a direct current system. Then a transmission of electrical energy between the system SEPS and the system MEPS is realized by means of a bidirectional converter of alternating current onto direct current I direct current onto alternating current 353, wherein the converter is arranged in the charging station 35, or alternatively by means of a bidirectional converter of alternating current onto direct current I direct current onto alternating current 353a installed in the vehicle 1, 2 (as Indicated in the figures Pos. I and FIG. 1).

For appropriate effecting settlements in virtue of a generation, a storage, a transmission, a distribution and a trade of electrical energy in the presented example, it is indispensable to install an appropriate number of watthour meters. The illustrated scheme presents a system in which typical, known from the prior art, watthour meters are used having the structure depicted in the figure Pos. II.

A typical watthour meter 4, known from the prior art and presented in Pos. II, comprises: an input measuring system 41 processing analog values of current I and voltage U into digital values in specified time intervals; a system of digital processing of signals 42 which processes digital signals from the system 41 using a processor and effecting measurements of electrical energy in specified time intervals on the basis of the digital signals from the system 41 wherein to the measurements are assigned appropriate time tags originating from the realtime clock 43; a register 44 for registering values of the EE measurements evaluated in the system 42, wherein the values are registered in a digital form; and a system of digital processing of registered quantities 45, comprising a processor, which on the basis of the data drawn from the register 44 for an appropriate time interval presents a total energy or provides a profile of a total energy for a predetermined time interval or an arbitrary different desirable parameter characterizing a time variability of an EE flow in the line to which an input measurement system is connected.

Returning to the figure Pos. I, the watthour meters 36, 37, 38 (of a typical known type as presented in Pos. I) have to be installed in all connections of the sources 31, 32, of the receivers 34 and of the charging stations 35 to the transmission-distribution network 33. Furthermore, the watthour meters 352 of the same type have to be installed also in each of the charging station 35 terminals 351, or alternatively in each of vehicles 1, 2 in the output EE transmission line 133, 233 a watthour meter 352a is to be installed.

The electric/hybrid vehicle 1, 2 constitutes a mobile electrical power system which at a given moment may by connected to an arbitrary but only one terminal 351 of an arbitrary but only one charging station 35. On that account, for the purpose of appropriate evaluation of electrical energy flows between the system SEPS and the systems MEPS of vehicle, it is required at least either installing in each of terminals 351 as many watthour meters 352 as many vehicles with the systems MEPS exists being enabled for connecting to the charging stations 35 and assigning each of such meters 352 to an individual system MEPS; or alternatively, in case when the meters 52a are installed in vehicles, installing In each of the systems MEPS as many watthour meters 352a as many terminals 351 exist in all charging stations 35 and assigning each of such meters 352a solely to one individual terminal 351 of each of the stations 35. Taking into account a great number of vehicles and charging stations with a plurality of terminals, a number of watthour meters 352, 352a required to be installed is enormous.

Additionally, in case where in vehicle charging/discharging stations 35 many entities trading electrical energy operate, from and to which appropriately systems MEPS of vehicles are able to selectively draw/buy and/or supply/sell electrical energy—what actually exists or will happen in the near feature—then each of the meters 1321, 2321 will have to be multiplied by a number of these entities.

For the purpose of appropriate effecting settlements in the system MEPS in virtue of a generation, a storage, a transmission, a distribution and a trade of electrical energy in the presented system, it is furthermore indispensable to install additional internal watthour meters 1321, 2321 in the EE storage transmission lines 132, 232 and additional internal watthour meters 1341, 2343, 2344 in the transmission lines 134, 234 (2342, 2341).

Thus, the main problem making impossible a practical realization of the above discussed idea of providing for such systems a possibility of participating in a broadly understood electrical energy trade (electrical energy market) within a system MEPS and within a system SEPS connected to MEPS, consists in a necessity of installation of an enormous number of watthour meters.

Therefore the object of the present invention is to provide an electrical energy measuring system for a mobile electrical power system, which would ensure a complex measuring of electrical energy flows within such a mobile system and thanks to that would enable for practical participating in electrical energy market by different interested entities associated with an electrical/hybrid vehicle.

### SUMMARY OF THE INVENTION

In order to accomplish the aforementioned and other objects, an electrical energy (EE) measuring system according to the present invention has been provided for a mobile electrical power system (MEPS) comprising an electrical energy storage connected by an electrical energy transmission system to at least one electrical energy receiver and/or at least one electrical energy source, and to at least one output connectable to a stationary electrical power system (SEPS), wherein the EE measuring system comprises:
an input measuring system having inputs designed for connecting to an electrical energy transmission line of the EE storage connected directly to the EE storage and comprising;
a voltage detector generating an analog voltage measuring signal representing a voltage of electrical energy flowing through the EE transmission line of the EE storage;
a current detector generating an analog current measuring signal representing a current of electrical energy flowing through the EE transmission line of the EE storage;
an input converter converting the voltage and current analog measuring signals respectively into voltage and current digital measuring signals;
a system of digital processing of signals comprising a processor generating, on the basis of the voltage and current digital signals of the input converter and a clock signal of a realtime clock, electrical energy measuring signals representing an electrical energy flow through the EE transmission line of the EE storage including at least electrical energy value and a direction of an electrical energy flow;
at least one main register in which said EE measuring signals representing electrical energy flow through the EE transmission line of the EE storage are registered, wherein the at least one main register is connected to an output of said system of digital processing of signals, which is characterized in that it additionally comprises
at least two registers in which the EE measuring signals of the system of digital processing of signals are registered, wherein the registers comprise:
at least one first register in which EE measuring signals of electrical energy flowing between the EE storage of the system MEPS and the system SEPS, representing an EE flow in an output electrical energy transmission line are registered, and
the second register in which EE measuring signals of electrical energy flowing within the system MEPS between the EE storage and the EE receiver and/or the EE source, representing an EE flow in an receiver/source electrical energy transmission line, are registered,
which are connected to the output of the system of digital processing of signals through
a switching redirection system in which a through path of a signal transmission is dependent on a state of its control inputs, wherein the switching redirection system transfers a signal from one of its inputs, which is connected to the output of the system of digital processing of signals, to a selected one of its at least two outputs, wherein each of these at least two outputs is connected to a different of the at least two registers, depending on a state of a signal at the first control input thereof, wherein the first control input is connectable to a source of a signal of a status of a connection of the output of EE transmission line of the system MEPS to the system SEPS.

In case when the system MEPS comprising the EE storage connected by the EE transmission system to at least one EE receive, at least one first EE source, at least one second EE source and to the at least one output connectable to the system SEPS, the EE measuring system according to the present invention additionally comprises
at least two additional registers, wherein
said switching redirection system comprises additionally the second control input connectable to a source of a signal of a status of a generation of electrical energy by at least one of the EE sources and of a status of charging/discharging of the EE storage of the system MEPS, wherein
in the first additional register in which EE measuring signals of electrical energy flowing within the system MEPS from the first EE source to the EE storage, representing an EE flow In a source EE transmission line, are registered, and in the second additional register in which EE measuring signals of electrical energy flowing within the system MEPS from the second EE source to the EE storage (22) representing an EE flow in a receiver/source EE transmission line, are registered, while
in said second register EE measuring signals of electrical energy flowing within the system MEPS from the EE storage to the EE receiver, representing an EE flow in a receiver/source EE transmission line, are registered.

For such a system the first EE source is preferably a non-renewable source, preferably a combustion engine, and the second EE source is preferably a renewable source, preferably a braking energy recovering system of the system MEPS.

According to the preferred embodiments, the system of digital processing of signals comprises an input for delivering a signal of identification of a point of a connection of the system MEPS to the system SEPS from a source of the signal of an identification of a point of a connection of the system MEPS to the system SEPS, and puts an information contained in this signal of an identification into the EE measuring signal. Furthermore an information identifying a given terminal together with the EE measuring signal are preferably registered in the at least one first register.

In another preferred embodiment of the present invention the system of digital processing of signals comprises an input for delivering a signal of a selection of an electrical energy seller and/or an input for delivering a signal of a selection of an electrical energy buyer, from a source of a signal of a selection of a seller that sells EE drawn by the system MEPS from the system SEPS and/or a buyer that buys EE supplied by the system MEPS to the system SEPS, and puts an information contained in the signal of an EE seller selection and/or in the signal of an EE buyer selection Into the EE measuring signal.

According to the present invention the system of digital processing of signals preferably additionally comprises an input for delivering a signal of a status of a generation of usable mechanical energy by the combustion engine and of a status of charging/discharging of the EE storage from the signal source.

According to the present Invention it may also be advantageous if the system of digital processing of signals additionally puts an information related to a status of a generation of usable mechanical energy by the combustion engine and to a status of charging/discharging of the EE storage into the EE measuring signal.

Furthermore according to the present invention it is advantageous if information of an identification of a given seller that sells electrical energy drawn by the system MEPS from the system SEPS/a given buyer that buys electrical energy supplied by the system MEPS to the system SEPS in case when the system MEPS is connected to the system SEPS, or information of an identification of a status of a generation of usable mechanical energy by the combustion engine and information of identification of a status of charging/discharging of the EE storage into the EE measuring signal, together with the EE measuring signal are additionally registered in the main register.

The preferred embodiment of the switching redirection system of the present invention additionally comprises the third control input connectable to the source of the signal of an identification of a point of a connection of the system MEPS to the system SEPS, while the EE measuring system comprises a number of the first registers, wherein each of these first registers is assigned to only one single point of a connection of the system MEPS to the system SEPS.

The preferred embodiments of the EE measuring systems according to the present invention comprise a number of the main registers connected to the output of the system of digital processing of signals through a switch transmitting a signal from its one input connected to the output of the system of digital processing of signals to a selected one of a number of its outputs, wherein each of these outputs is preferably connected to a different register of a number of the main registers, depending on a state of a signal on the switch control input that is connectable to the source of a signal of a selection of a EE seller and/or of a signal of selection of a EE buyer. Furthermore this switch control input, that is connectable to the source of a signal of a selection of a EE seller and/or of a signal of selection of a EE buyer, preferably is additionally connectable to the source of a signal of a status of a generation of usable mechanical energy by the combustion engine and of a signal of a status of charging/discharging of the EE storage, wherein each of these main registers is preferably assigned only to a one single EE seller and/or EE buyer, and to electrical energy originating from particular EE sources in the system MEPS and to electrical energy utilized for driving the vehicle.

In preferred embodiments of the present invention, a signal of an appropriate directional characteristic of electrical energy losses on the path of electrical energy transmission to and/or from the EE storage, is delivered from a register of directional characteristics of electrical energy losses to the input of the processor of the system of digital processing of signals, wherein the signal is considered by the processor in generation of EE measuring signals appearing at its output.

The EE measuring system according to the present invention preferably comprises the superior system of digital processing of the registered quantities, the inputs of which are connected to said registers and which comprises a processor that generates output signals representing total EE flows in particular lines and sublines of the system MEPS, total EE flows from/to particular EE sellers/buyers and total EE flows from/to particular terminals of charging/discharging stations and time courses of these flows, on the basis of EE measuring signals registered in said registers.

Particular EE sellers/buyers are preferably associated with the system SEPS, whereas the processor preferably generates output signals representing total flows of electrical energy originating from particular EE sources in the system MEPS and total flows of electrical energy utilized for driving the vehicle on the basis of the EE measuring signals registered in said registers.

The output signals of the superior system of digital processing of the registered quantities are preferably made available on a display installed in the vehicle in which the system MEPS is installed.

Finally, the preferred embodiments of the EE measuring systems according to the present Invention comprise a source of a signal of a selection of a seller that sells electrical energy drawn by the system MEPS from the system SEPS and/or a buyer that buys electrical energy supplied by the system MEPS to the system SEPS, wherein the source cooperates with a display and/or a control panel installed in the vehicle in which the system MEPS is installed.

The proposed according to the present invention measuring system enables for measuring flows of electrical energy within mobile electrical power systems during autonomic operation mode as well as in a state of a connection to a stationary electrical power system, with using only one measuring system installed in a vehicle comprising a given mobile electrical power system , and using only measuring signals of voltage and current occurring in an electrical energy transmission line of an electrical energy storage.

### DESCRIPTION OF THE FIGURES

The other features of the invention shall be presented below in exemplary embodiments and in connection with the attached drawings on which:

Figs. Pos. I and II present examples of connection of exemplary mobile electrical power systems (MEPS) of vehicles to a stationary electrical power system (SEPS);

FIG. 1 presents a scheme of a connection of mobile electrical power systems provided with electrical energy measuring systems according to the present invention through charging station terminals to a stationary electrical power system;

FIG. 2 presents a block scheme of the first embodiment of an electrical energy measuring system according to the present invention,

FIG. 3 presents a block scheme of the second embodiment of an electrical energy measuring system according to the present invention,

FIG. 4 presents a block scheme of the third embodiment of an electrical energy measuring system according to the present invention, and

FIG. 5 presents a block scheme of the fourth embodiment of an electrical energy measuring system according to the present invention.

### DETAILED DESCRIPTION OF THE INVENTION EMBODIMENTS

Numerical references of the elements performing the same or similar functions remain the same on all figures, wherein, if it is appropriate, suffixes are employed (for example 5a) indicating variants of corresponding elements or features (for example 5).

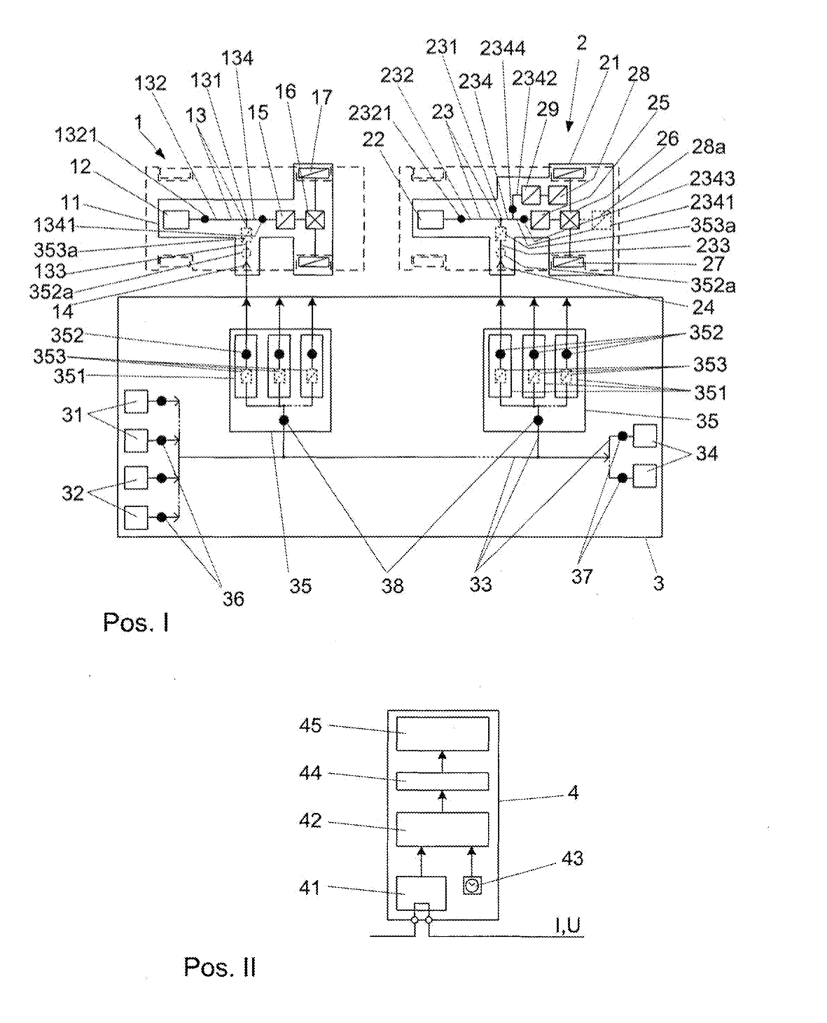

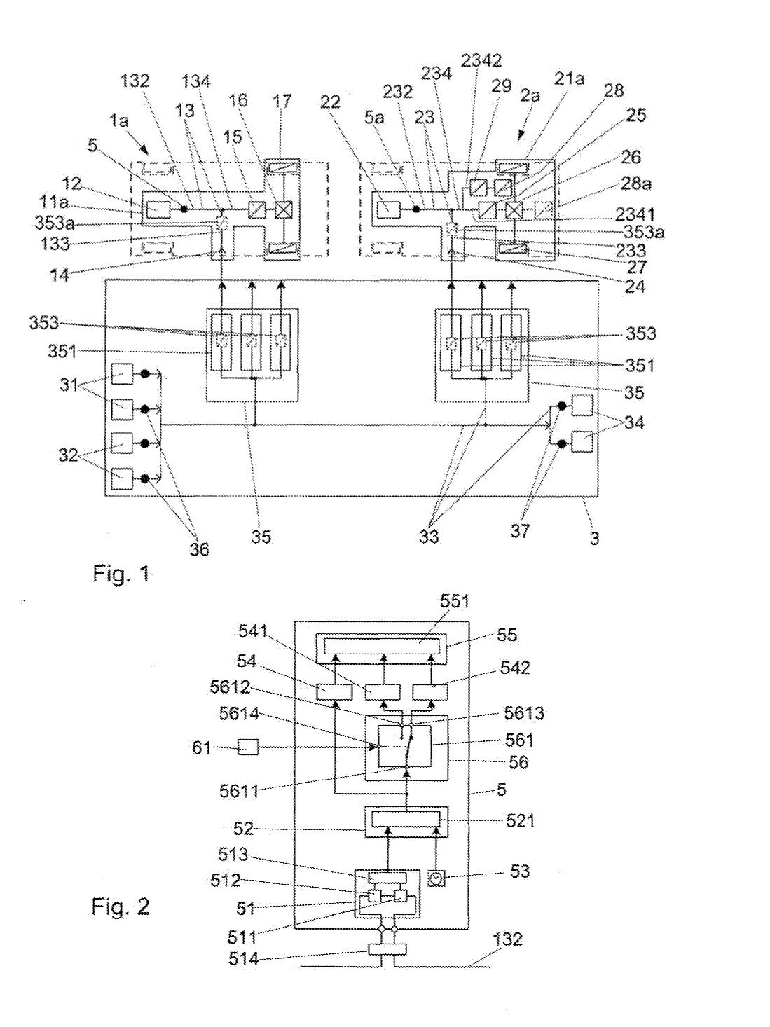

The mobile electrical power systems 11a, 21a of vehicles 1a, 2a as presented In FIG. 1 have a structure analogical to the structure of the systems 11, 21 of the vehicles 1,2 from figure Pos. I. In comparison with the systems 11 and 21 provided with watthour meters 1321, 1341 and 2321, 2343, 2344, each of the systems 11a and 21a is provided only with one inventive watthour meter according to the present invention 5 and 5a respectively, the input measuring system of which is installed on the electrical energy transmission line 132, 232 of the EE storage. Employment of meters 5, 5a according to the present invention in the mobile electrical power system 11a, 21a furthermore enables for resigning from employment of the watthour meters 352 1n the charging station terminals 351, which were indispensable in the solution from the figure Pos. 1.

The measuring system 5 according to the present invention as presented in FIG. 2 is designed for installation in the place of the meter 1321 in the system 11 of the vehicle 1 having electrical drive from the figure Pos. I. The system comprises a majority of elements functionally analogical as well as analogical in the matter of structural localization relative to a typical meter 4 of the figure Pos. 1, i.e. an input measuring system 51, a system of digital processing of signals 52, a realtime clock 53, the main register 54, the first register 541, the second register 542 and a system of digital processing of the registered quantities 55.

The input measuring system 51 has an input designed for connecting to the EE transmission line 132 of the EE storage 12, a voltage detector 511 and a current detector 512 generating analog measuring signals respectively of voltage and current that represent respectively a voltage and a current of electrical energy flowing through this EE storage transmission line 132 in the place of installation of the detectors. In the presented embodiment, the inputs of the detectors 511, 512 are connected to the line 132 directly through an appropriate intermediate measuring transformer arrangement 514. The outputs of the detectors 511, 512 are connected to the output converter 513 converting analog measuring signals of voltage and current into output digital signals of voltage and current.

The system 52 of digital processing of signals comprises a processor 521, which on the basis of the digital measuring signals of voltage and current delivered to the inputs thereof from the output converter 513 and on the basis of the clock signal of the realtime clock 53, generates measuring EE signals representing an EE flow in the EE storage transmission line 132 in the place of installation of detectors 511, 512 of the input measuring system 51 by determining values of electrical energy and direction of flow of electrical energy.

Similarly as in the typical watthour meter 4 shown in Pos. I, in the system 5 the EE measuring signals from the system 52 are directed to the main register 54 and additionally they are concurrently delivered to the input 5611 of a switching redirection system 56 leading to the two different separate registers 541, 542. The quantities registered in the main register 54 correspond to the quantities registered in the register 44 of the meter 4 installed as the watthour meter 1321 from the figure Pos. I. The redirection system 56 comprises a double-throw switch 561 having the input contact 5611 connected to the output of the processor 521, the first output contact 5612 connected to the input of the first register 541 and the second output contact 5613 connected to the input of the second register 542.

The position of the switch 561 is determined by the signal delivered to its control contact 5614, which in this embodiment is connected to a source 61 of a signal of a status of a connection of the output 14 of the output EE transmission line 133 of the system MEPS 11 a to the terminal 351 of the charging station 35 of the system SEPS 3. The source 61 may have for example a form of a sensor of a mechanical (and thus also electrical) connection of a plug of the output 14 with a socket of the terminal 351 which is installed on the output 14 or In the terminal, or a proximity sensor automatically generating an activity signal of a connection in case of appropriate; vehicle approach to a charging station terminal.

In case when the control signal indicates a state of a connection of the system MEPS to the system SEPS, then the switch 561 connects the contacts 5611 and 5612, and the measurements of electrical energy (received or delivered by the system MEPS respectively from or to the system SEPS) are registered in the register 541.

The quantities registered in the register 541 correspond to the quantities registered in the register 44 of the meter 4 from the figure Pos. II installed as the meter 352 in the figure Pos. I, on the assumption that electrical energy losses on the path of EE flow between the places of EE measurement by the meters 1321 and 352 from the figure Pos. I are omissible (do not occur).

However, when the control signal indicates a state of a disconnection of the system MEPS from the system SEPS, then the switch 561 connects the contacts 5611 and 5613, and the EE measurements (representing an internal EE flow between the EE storage of the system MEPS and the EE source, which is a braking energy recovery system, and the EE receiver, which is driving electrical motor) are registered in the register 542. The quantity registered in the register 542 correspond to the quantities registered in the register 44 of the meter 4 form the figure Pos. II installed as the meter 1341 from the figure Pos. II, on the assumption that electrical energy losses on the path of EE flow between the places of EE measurement by the meters 1321 and 1341 from the figure Pos. I are omissible (do not occur).

The outputs of the registers 54, 541, 542 are connected to the inputs of the superior system of digital processing of the registered quantities 55. The superior system 55 comprises a processor 551, which on the basis of the EE measuring signals registered in the registers 54, 541, 542 generates output signals representing summary EE quantities and time courses of electrical energy flowing in the internal transmission system 13 of the system MEPS 11a, including courses representing flows of particular electrical energy types depending on a type of a source/receiver of energy. On the basis of these courses, it is in turn possible to determine the sources of originations of electrical energy accumulated in the EE storage of the system MEPS with a separation into energies originating from particular EE sources in the system MEPS or in the system SEPS, and destination allocation of electrical energy dispensed from the EE storage. The outputs of the processor 551 are connected to a display (not shown in the drawing) installed in a vehicle driver's compartment and thanks to that signals generated in the superior system 55 may be provided to a driver.

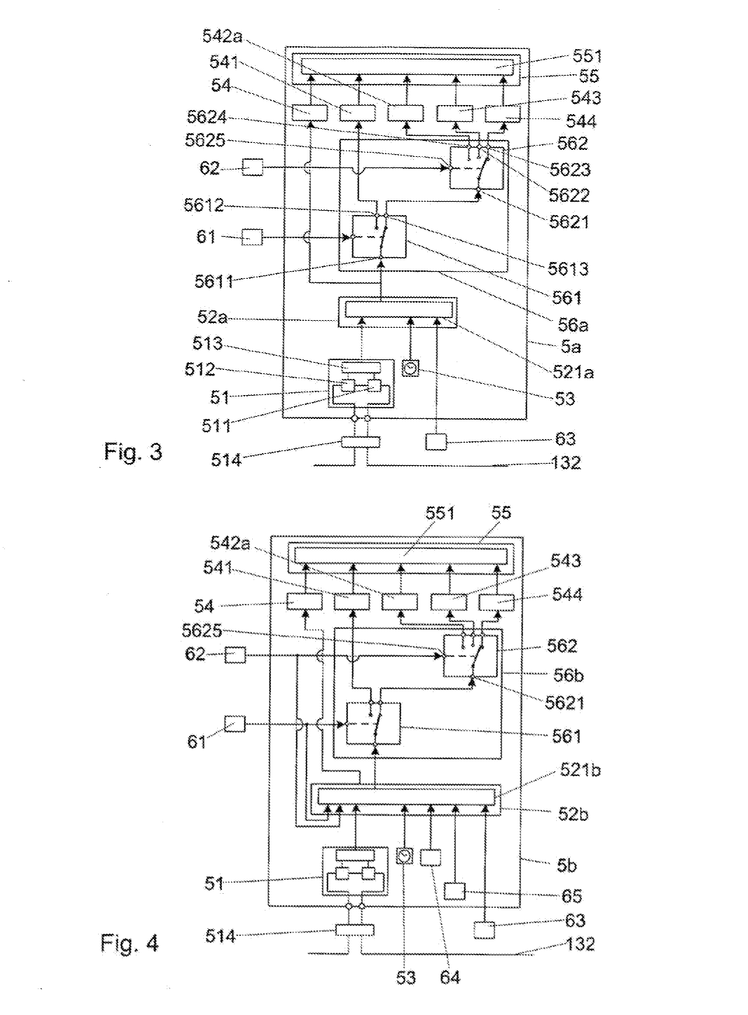

The measurement system 5a presented in figure FIG. 3 is designed for installation in the place of installation of the meter 2321 in the system 21 of the hybrid vehicle 2 from the figure Pos. I, in comparison with the system 5, in this embodiment the redirection system 56a comprises the switch 561 connected to the second switch 562 in a cascade structure.

The output contact 5613 of the switch 561, which is in an active mode in the state of a disconnection of the system MEPS from the system SEPS, is connected to the input contact 5621 of the switch 562. In the switch 562, the first output contact 5622 is connected to the input of the third register 543, the second output contact 5623 is connected to the fourth register 544 and the third output contact 5624 is connected to the register 542a. A source 62 of signals of a status of a generation of usable mechanical energy by the combustion engine 28 (optionally 28a) and of a status of charging/discharging of the EE storage 22 is connected to the control contact 5625 of the second switch 562.

In case when the control signal from the source 62 indicates for the state of generation of usable mechanical energy by the combustion engine 28 and charging of the EE storage, then the switch 562 connects the contacts 5621 and 5622 and the measurements of electrical energy (generated by the combustion engine and delivered to the EE storage of the system MEPS) are registered in the register 543. The quantities registered in the register 543 correspond to the quantities registered in the register 44 of the meter 4 from the figure Pos. 1 installed as the meter 2344 from the figure Pos. I, on the assumption that electrical energy losses on the path of EE flow between the places of EE measurement by the meters 2321 and 2344 from the figure Pos. I are omissible (do not occur).

Whereas when the control signal from the source 62 indicates for the state of a generation of usable mechanical energy by the combustion engine 28 or indicates for the engine 28 idle running, and the vehicle is not connected to the charging station and the EE storage is charged, then the switch 562 connects the contacts 5621 and 5623 and the EE measurements (of EE generated by the braking energy recovering system and delivered to the EE storage of the system MEPS) are registered in the register 544. The quantities registered in the register 544 correspond to the quantities registered in the register 44 of the meter 4 from the figure Pos. II installed as the meter 2343 from the figure Pos. I. on the assumption that electrical energy losses on the path of EE flow between the places of EE measurement by the meters 2321 and 2344 from the figure Pos. I are omissible (do not occur).

In a result of such a solution, in a state of a disconnection of the system MEPS 21 from the system SEPS in the system 5a and of the signal from the source 62 indicating a lack of charging of the EE storage, in the switch 562 contacts 5621 and 5624 are connected to each other inducing that in the register 542a are registered only the values of the measurement signal corresponding to the EE flow from the EE storage 22 to the engine 25, i.e. to the EE flow impelling the vehicle 2a.

In the register 542a is registered electrical energy dispensed from the EE storage 22 and utilized for driving the vehicle. Whereas in the registers 543 and 544 are registered measurements of flows of electrical energy used for charging the EE storage 22 originating from different EE sources installed in the system MEPS. In case of the vehicle 2a from the figure FIG. 1, these sources are the combustion engine 28 (optionally 28a) processing non-renewable primary energy and the braking energy recovering system 27 processing renewable primary energy, for which may be implemented for example an appropriate support system.

To one of the inputs of the processor 521 a of the system 52a is connected a source 63 of an identification signal of the charging station terminal to which the output 24 of the system MEPS 21 is connected. The processor 521a takes into consideration the information transferred in this signal by putting in a measuring EE signal an information identifying a given terminal 351 from or to which electrical energy is respectively drawn or supplied. Optionally, the information identifying a given terminal 351 together with a measuring EE signal may be additionally registered in the register 541.

The system 5b shown in FIG. 4 constitutes a development of the system 5a of FIG. 3. A possible application of the system 5b occurs for cases where substantial energy losses occur and their consideration is indispensable. In this system 5b, the signals from the source 61 of a status signal of a connection of the output EE transmission line of the system MEPS to a charging station terminal of the system SEPS, and from the source 62 of a status signal of a generation of usable mechanical energy by the combustion engine and of a status signal of charging/discharging of a hybrid vehicle electrical energy storage, are delivered also to the input of the processor 521b of the system 52b. Additionally to the input of this processor 521b is connected the output of a register 64 of directional characteristics of electrical energy losses. The register 64 comprises sets of data/parameters characterizing processes of a generation of losses in particular paths of possible electrical energy transmission in directions to and from the EE storage of the system MEPS. In particular, the register 64 comprises characteristics of a generation of internal losses during internal electrical energy transmission between the EE storage and the EE sources/receivers of the system MEPS, and characteristics of a generation of external losses during electrical energy exchange between the EE storage of the system MEPS and the system SEPS. A directional character of these characteristics means that each set of data/parameters corresponds to a specific direction of electrical energy flow along a given path composed of a given pair of electrical energy transmission system lines:
the electrical energy transmission line of the electrical energy storage, the output transmission line, the receiver/source transmission line.

The processor 52 b on the basis of the signal from the sources 61, 62 determines particular path of electrical energy transmission which is used to select appropriate characteristic of electrical energy losses, and on the basis of digital measuring signals of voltage and current the processor 521b determines directivity of the selected type of characteristic. Subsequently, on the basis of data/parameters for the selected directional characteristic received from the register 64, the processor evaluates electrical energy losses and considers them in EE measuring signal or registers their values in appropriate registers, wherein consideration of the evaluated losses takes place later on the higher level of processing of measurements carried out by the system of digital processing of the registered quantities 55. The register 54 is connected to a separate output of the system 52b on which appear measuring signals in which energy losses are not considered in the above described manner.

Moreover, the system 5b comprises a source 65 of a signal of a selection of a seller that sells electrical energy drawn by the system MEPS from system SEPS/of a buyer that buys electrical energy supplied by system MEPS to system SEPS, wherein the source 65 is connected to one of the Inputs of the processor 521b of the system 52b. The source 65 cooperates with a display and a control panel Installed in a vehicle driver's compartment and enables for a driver by himself to indicate an entity to which electrical energy from an electrical energy storage is sold or from which electrical energy for charging an electrical energy storage is bought. The processor 521b puts in a EE measuring signal an appropriate identification information loaded by means of the control panel and/or of the display wherein the information corresponds to the information contained in the EE seller/buyer selection signal received from the source 65. Optionally, the processor 521b may additionally put in the EE measuring signal an appropriate information corresponding to the information from the source 62 of the status signal of a generation of usable mechanical energy by the combustion engine 28 (optionally 28a) and of the status signal of charging/discharging of the EE storage 22. Furthermore optionally in the register 54 may be additionally registered information identifying a seller that sells electrical energy drawn by system MEPS from system SEPS/a buyer that buys electrical energy supplied by system MEPS to system SEPS in case when system MEPS is connected to system SEPS, or information identifying a status of a generation of usable mechanical energy by the combustion engine 28 (optionally 28a) and a status of charging/discharging of the EE storage 22 together with EE measuring signal.

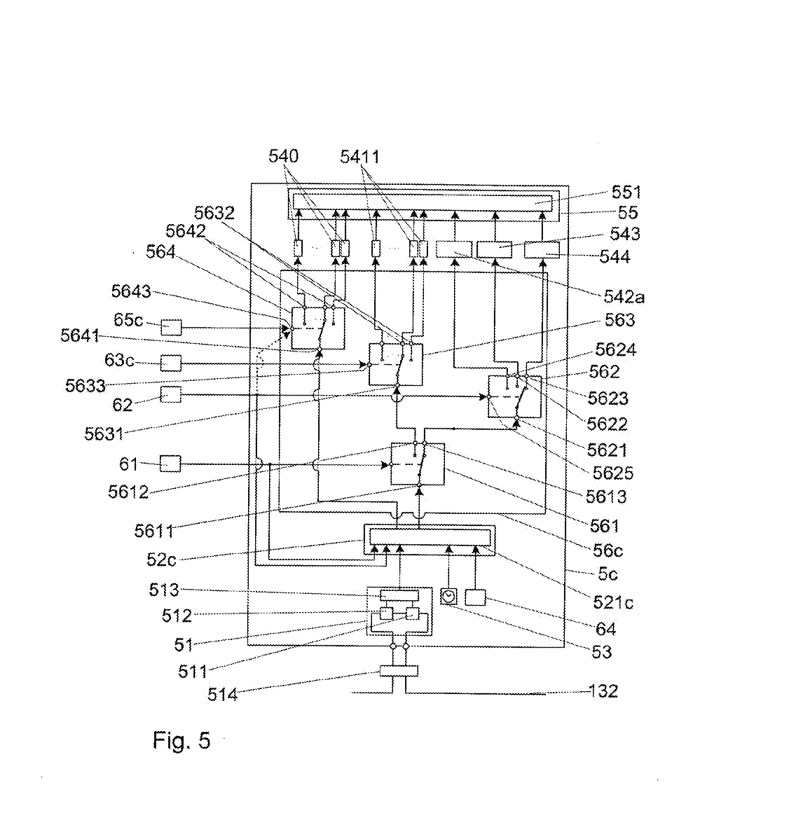

Further embodiment 5c of an electrical energy measuring system according to the present invention is presented in FIG. 5. This embodiment is an example of further functional development of the system 5b from FIG. 4. The system 5c is provided with the switching redirection system 56c of a more complicated structure having additional multi-throw switches 563 and 564. The input contact 5631 of the switch 563 is connected to the first output contact 5612 of the switch 561 which is active during a connection of the system MEPS to a terminal of a charging/discharging station of the system SEPS. Each of the output contacts 5632 of the switch 563 is connected to a separate individual register from set of registers 5411. The source 63c of a signal of identification of a connection point of a connection of the system MEPS to the system SEPS (for example the signal of identification of a terminal of a charging/discharging station) is connected to the control contact 5633 of the switch 563. Thanks to such a structure—as contrasted with the system 5b, instead of putting an information contained in an identification signal of a connection point by the processor of a system of digital processing of signals into a EE measuring signal —with employment of the system 5c during a connection of the system MEPS to the system SEPS, the system of digital processing of signals 52c provides at its output a “clear” EE measuring signal which by means of the switching redirection system 56c is directed to an appropriate register from the group of registers 5411 corresponding to a selected point of connection of the system MEPS to the system SEPS. The input contact 5641 of the switch 564 is connected to the measuring output of the processor 521c, whereas each of the output contacts 5642 of the switch 564 is connected to a separate individual register from the group of registers 540. The source 65c of a signal of a selection of an electrical energy seller/buyer is connected to the control contact 5643 of the switch 564, wherein in this embodiment the source 65c is an element external relative to the measuring system 5c. Optionally, to the control contact 5643 of the switch 564 may be additionally connected the source 62 of a status signal of a generation of usable mechanical energy by the combustion engine 28 (optionally 28a) and of a status signal of charging/discharging of the EE storage 22. Thus, in a case when the system MEPS is connected to the system SEPS depending on a seller/buyer selected in a given moment the “clear” EE measuring signals are routed by means of the switch 564 in such a manner that the signals are registered in a separate individual register from the group of the registers 540 which is assigned to a given seller/buyer, and furthermore, in case when the system MEPS is disconnected from system SEPS depending on the signal delivered by the signal source 62, the “clear” EE measuring signals are routed by means of the switch 564 in such a manner that the signals are registered in a separate individual register from the group of the registers 540 which is assigned to electrical energy generated by the combustion engine 28 (optionally 28a), electrical energy generated during vehicle braking or electrical energy utilized for driving a vehicle. By analogy to the system 5b of the figure FIG. 4, the switch 564 directing signals to the registers 540 is connected to a separate output of the system 52c at which appear measuring signals without regard to energy transmission losses in the above described manner.

1-17. (canceled)

18. An electrical energy (EE) measuring system for a mobile electrical power system (MEPS) including an electrical energy (EE) storage connected by an electrical energy transmission system to at least one electrical energy receiver and/or to at least one electrical energy source, and to at least one output connectable to a stationary electrical power system (SEPS), comprising:
an input measuring system having inputs adapted for connecting to an electrical energy (EE) transmission line of the EE storage connected directly to the EE storage,
a voltage detector generating an analog voltage measuring signal representing a voltage of electrical energy flowing through the EE transmission line of the EE storage,
a current detector generating an analog current measuring signal representing a current of electrical energy flowing through the EE transmission line of the EE storage,
an input convertor converting the voltage and current analog measuring signals respectively into voltage and current digital measuring signals;
a digital signal processing system for generating, on the basis of the voltage and current digital signals of the input convertor and a clock signal of a realtime clock, electrical energy (EE) measuring signals representing an electrical energy flow through the EE transmission line of the EE storage including at least electrical energy value and a direction of an electrical energy flow;
at least one main register in which said EE measuring signals representing electrical energy flow through the EE transmission line of the EE storage are registered, wherein the at least one main register is connected to an output of said digital signal processing system,
at least two registers in which the EE measuring signals of the digital signal processing system are registered, wherein the at least two registers comprise:
at least one first register in which EE measuring signals of electrical energy flowing between the EE storage of the system MEPS and the system SEPS, representing an EE flow in an output electrical energy transmission line, are registered, and,
a second register in which EE measuring signals of electrical energy flowing within the system MEPS between the EE storage and the EE receiver and/or the EE source, representing an EE flow in a receiver/source electrical energy transmission line, are registered,
the at least two registers being connected to the output of the digital signal processing system, through a switching redirection system in which a through path of a signal transmission is switched dependent on a state of control inputs, wherein the switching redirection system transfers a signal from one input, which is received from the output of the digital signal processing system, to a selected one of at least two outputs, wherein each output is connected to a different one of the at least two register, depending on a state of a signal at a first control input thereof, wherein the first control input is connectable to a source of a signal on a status of a connection of the output of the EE transmission line of the system MEPS to the system SEPS.

19. The EE measuring system according to claim 18 further comprising:
at least two additional registers, wherein said switching redirection system additionally has a second control input connectable to a source of a signal on a status of a generation of electrical energy by at least one EE source and on a status of charging/discharging of the EE storage of the system MEPS, wherein:
in a first additional register, measured signals of electrical energy flowing within the system MEPS from the a first EE source to the EE storage, representing an EE flow in a source EE transmission line, are registered, and
in a second additional register, measured signals of electrical energy flowing within the system MEPS from a second EE source to the EE storage representing an EE flow in a receiver/source EE transmission line, are registered, wherein:
in said second register, measured signals of electrical energy flowing within the system MEPS from the EE storage to the EE receiver, representing an EE flow in a receiver/source EE transmission line, are registered.

20. The EE measuring system according to claim 18, wherein the first EE source is a non-renewable source comprising a combustion engine, and the second EE source is a renewable source comprising a braking energy recovery system of the system MEPS.

21. The EE measuring system according to claim 19, wherein the first EE source is a non-renewable source comprising a combustion engine, and the second EE source is a renewable source comprising a braking energy recovery system of the system MEPS.

22. The EE measuring system according to claim 18, wherein the digital signal processing system has an input for delivering a signal of identification of a point of a connection of the system MEPS to the system SEPS from a source of the signal of an identification of a point of a connection of the system MEPS to the system SEPS, and
the digital signal processing system putting an information contained in this signal of an identification into the EE measuring signal.

23. The EE measuring system according to claim 22, wherein an information identifying a given terminal together with the EE measuring signal are registered in the at least one first register.

24. The EE measuring system according to claims 18 wherein the digital signal processing system has an input for delivering a signal of a selection of an electrical energy (EE) seller and/or an input for delivering a signal of a selection of an electrical energy (EE) buyer, from a source of a signal of a selection of a seller that sells electrical energy drawn by the system MEPS from the system SEPS and/or a buyer that buys electrical energy supplied by the system MEPS to the system SEPS, and wherein,
the digital signal processing system puts an information contained in the signal of an EE seller selection and/or in the signal of an EE buyer selection into the EE measuring signal.

25. The EE measuring system according to claim 24, wherein the digital signal processing system has an input for delivering a signal of a status of a generation of usable mechanical energy by a combustion engine and of a status of charging/discharging of the EE storage from the signal source.

26. The EE measuring system according to claim 24, wherein the digital signal processing system has an output of a status of a generation of usable mechanical energy by the combustion engine and a status of charging/discharging of the EE storage into the EE measuring signal.

27. The EE measuring system according to claim 25, wherein the digital signal processing system has an output of a status of a generation of usable mechanical energy by the combustion engine and a status of charging/discharging of the EE storage into the EE measuring signal.

28. The EE measuring system according to claim 24, wherein information of an identification of a given seller that sells electrical energy drawn by the system MEPS from the system SEPS, and a given buyer that buys electrical energy supplied by the system MEPS to the system SEPS when the system MEPS is connected to the system SEPS, or information of an identification of a status of a generation of usable mechanical energy by the combustion engine and a status of charging/discharging of the EE storage into the EE measuring signal, together with the EE measuring signal, are additionally registered in the main register.

29. The EE measuring system according to claim 18 wherein the switching redirection system has a third control input connectable to the source of the signal of an identification of a point of a connection of the system MEPS to the system SEPS, and wherein the EE measuring system further comprises a number of first registers, wherein each first register is assigned to only one single point of a connection of the system MEPS to the system SEPS.

30. The EE measuring system according to claim 18 further comprising a number of main registers connected to the output of the digital signal processing system through a switch for transmitting a signal from one input connected to the output of the digital signal processing to a selected one of a number of outputs, wherein each output is connected to a different register of a number of the main registers, depending on a state of a signal on the switch control input that is connectable to the source of a signal of a selection of an EE seller and/or of a signal of selection of an EE buyer.

31. The EE measuring system according to claim 30, wherein the control input of the switch is additionally connectable to the source of a signal of a status of a generation of usable mechanical energy by a combustion engine and of a signal of a status of charging/discharging of the EE storage, wherein:
each main register is assigned only to one single EE seller and/or one single EE buyer, and to electrical energy originating from particular EE sources in the system MEPS and to electrical energy utilized for driving the vehicle.

32. The EE measuring system according to claim 18, wherein a signal of an appropriate directional characteristic of electrical energy losses on the path of electrical energy transmission to and/or from the EE storage, is delivered from a register of directional characteristics of electrical energy losses to the input of the digital signal processing system, the signal being considered by the processor when generating EE measuring signals for output.

33. The EE measuring system according to claim 18, further comprising a superior system for digital processing of the registered quantities, inputs of which are connected to said registers and which include a processor that generates output signals representing:
total EE flows in particular lines and sublines of the system MEPS,
total EE flows from/to particular EE sellers/buyers and
total EE flows from/to particular terminals of charging/discharging stations and
time courses of these flows,
on the basis of EE measuring signals registered in said registers.

34. The EE measuring system according to claim 33, wherein the EE sellers/buyers are associated with the system SEPS, whereas the processor generates output signals representing total flows of electrical energy originating from particular EE sources in the system MEPS and total flows of electrical energy utilized for driving the vehicle on the basis of the EE measuring signals registered in said registers.

35. The EE measuring system according to claim 32, wherein the output signals of the superior system are made available on a display installed in the vehicle in which the system MEPS is installed.

36. The EE measuring system according to claim 24, further comprising a source of a signal of a selection of a seller that sells electrical energy drawn by the system MEPS from the system SEPS and/or a buyer that buys electrical energy supplied by the system MEPS to the system SEPS, wherein the source cooperates with a display and/or a control panel installed in the vehicle in which the system MEPS is installed.
